(19) United States
(12) Patent Application Publication
(10) Pub. No.: US 2021/0384049 A1
(43) Pub. Date: Dec. 9, 2021

(54) System and Method for Wet Chemical Etching in Semiconductor Processing

(71) Applicant: Tokyo Electron Limited, Tokyo (JP)

(72) Inventors: Derek William Bassett, Cedar Park, TX (US); Antonio Luis Pacheco Rotondaro, Austin, TX (US); Trace Quentin Hurd, Austin, TX (US); Hironobu Hyakutake, Kumamoto (JP); Kazuyoshi Mizumoto, Kumamoto (JP); Nobuaki Matsumoto, Tokyo (JP)

(21) Appl. No.: 17/088,339

(22) Filed: Nov. 3, 2020

Related U.S. Application Data
(60) Provisional application No. 63/034,977, filed on Jun. 4, 2020.

(51) Int. Cl. H01L 21/67

(52) U.S. Cl. CPC H01L 21/67086

(57) ABSTRACT

A wet etch system comprises an etching bath comprising an etching solution in a process tank inside an overflow tank flowing over an open top into the overflow tank. The etching bath has a top cover, a gas inlet, and a gas outlet above the etching solution. A gas flow system pumps inert gas into the gas inlet and extracts the gas through the gas outlet under positive pressure. The gas flow system may also bubble inert gas through the etching solution via injectors of a gas sparger in the process tank. A recirculation path connects a liquid outlet port coupled to the overflow tank to a liquid inlet port coupled to the process tank. A pump drives the etching solution to flow from the overflow tank, through a degasser in the recirculation path, back into the process tank, and overflow from the process tank into the overflow tank.

### CROSS-REFERENCE TO RELATED APPLICATIONS

This application claims the benefit of U.S. Provisional Application No. 63/034,977, filed on Jun. 4, 2020, which application is hereby incorporated herein by reference.

### TECHNICAL FIELD

The present invention relates generally to a system and method for semiconductor processing, and, in particular embodiments, to a system and method for wet chemical etching in semiconductor processing.

### BACKGROUND

Generally, a semiconductor device, such as an integrated circuit (IC) is fabricated by sequentially depositing and patterning layers of dielectric, conductive, and semiconductor materials over a substrate to form a network of electronic components and interconnect elements (e.g., transistors, resistors, capacitors, metal lines, contacts, and vias) integrated in a monolithic structure. Some of these have complex three-dimensional (3D) structures. Many of the processing steps used in IC fabrication such as surface cleaning, electroplating, chemical-mechanical planarization (CMP), and wet chemical etching use liquid reactants and solvents.

At each successive technology node, the demand for low cost drives minimum feature sizes lower to roughly double the component packing density. With lateral dimensions close to ten nanometers, very high aspect ratio structures (e.g., 3D memory cells, contacts, and vias) are being designed. Fabricating the structures includes wet processing such as wet chemical etchback, thereby challenging wet chemical processing technology to provide uniform chemical concentrations within a nanostructure as well as across a 300 mm wide substrate. Further innovations are to be made in wet chemical processing to meet the stringent specifications for precision, uniformity, and repeatability of process parameters in volume manufacturing.

### SUMMARY

In accordance with an embodiment of the present disclosure, a system for semiconductor processing includes an etching bath, which includes a process tank nested inside an overflow tank and has an open top, where the process tank is configured to allow an outflow of an etching solution over the open top into the overflow tank; a wafer boat holder disposed inside the process tank; a top cover configured to substantially seal the etching bath to gas and covering the top opening of the etching bath; a gas inlet disposed outside the process tank; and a gas outlet above a topmost level of the etching solution in the etching bath; and a gas flow system attached to the gas inlet and the gas outlet, where the gas flow system is configured to pump a chemically inert gas into the gas inlet and extract the chemically inert gas through the gas outlet under positive pressure.

In accordance with an embodiment of the present disclosure, a system for semiconductor processing includes an etching bath, which includes a process tank nested inside an overflow tank and has an open top, where the process tank is configured to allow an outflow of an etching solution over the open top into the overflow tank; a wafer boat holder disposed inside the process tank; a top cover configured to substantially seal the etching bath to gas and covering the top opening of the etching bath; and a gas sparger which includes a plurality of gas injectors distributed uniformly across a bottom region of the process tank and coupled to a gas flow system configured to bubble a chemically inert gas through the etching solution in the process tank.

In accordance with an embodiment of the present disclosure, a method of semiconductor processing includes filling a process tank of an etching bath disposed inside an overflow tank of the etching bath with an etching solution, immersing a wafer boat with a substrate onto a wafer boat holder inside the process tank, pumping the etching solution from the overflow tank to flow through a degasser, and returning into the process tank, where the pumping of the etching solution causes the etching solution to overflow from the process tank into the overflow tank; and pumping a chemically inert gas through a gas inlet into a region above a topmost level of the etching solution in the overflow tank and extracting the chemically inert gas through a gas outlet under positive pressure.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a perspective view of a portion of an etching bath, in accordance with an embodiment;

FIG. 2 illustrates a cross-sectional view of an etching bath and a schematic of a recirculation path of a wet chemical processing system, in accordance with various embodiments;

FIG. 3 illustrates a planar view of a gas sparger disposed in the portion of the etching bath illustrated in FIG. 2 in accordance with an embodiment;

FIG. 4 illustrates a cross-sectional view of a bubble column degasser in accordance with an embodiment of the wet chemical processing system illustrated in FIG. 2; and

FIGS. 5A and 5B are cutaway diagrams of a membrane filter degasser in accordance with an embodiment of the wet chemical processing system illustrated in FIG. 2.

### DETAILED DESCRIPTION OF ILLUSTRATIVE EMBODIMENTS

This disclosure describes embodiments of wet chemical etching systems and methods in semiconductor processing that provide the advantage of improved uniformity of wet chemical etch processes achieved by reducing a concentration of dissolved oxygen (DO) in an etching solution. The invention is illustrated with an example embodiment of a wet chemical etching system and method for processing a substrate to etch silicon with a tetramethylammonium hydroxide (TMAH) solution as an etching solution, as described in further detail below. The systems and methods used to reduce the concentration of DO in the etching solution in the example embodiment may be extended to other applications using other etching solutions for etching other materials, for example, III-V semiconductors, silicon germanium, silicon carbide, and other applications that benefit from low dissolved oxygen.

Wet chemical etching is used in various semiconductor processing applications such as to strip sacrificial layers (e.g., remove masking layers), as an etchback technique, surface preparation (e.g., remove native oxide), and surface cleaning (e.g., particle removal and descumming). Any variation in the etching rate during the wet chemical etching, such as across the wafer, wafer to wafer, or lot to lot, may reduce the manufacturing yield. Furthermore, variation of etching rate along the depth direction of high aspect ratio features is becoming increasingly important as wet chemical processing finds use in critical process steps in the fabrication of three-dimensional (3D) dynamic random access memory (DRAM) and 3D NAND memory cells, and structures such as contacts and vias used in middle of-line (MOL) and back-end-of-line (BEOL). A uniform etch rate along the depth of high aspect ratio nanostructures benefits the manufacturing yield of high density IC's. The inventors of this application have identified that the presence of dissolved oxygen (DO) in etching solutions such as TMAH can cause variation in the etching rate of materials such as polysilicon. Their theoretical and experimental analyses suggest that etch rate variation up to a depth of a few microns along the vertical direction of structures with nanometer-scale dimensions may be kept within a tolerable limit if the DO concentration is kept low (e.g., at about 100 ppb or less). Hence, it is advantageous to reduce the concentration of DO in the etching solution used for the respective etch chemistry.

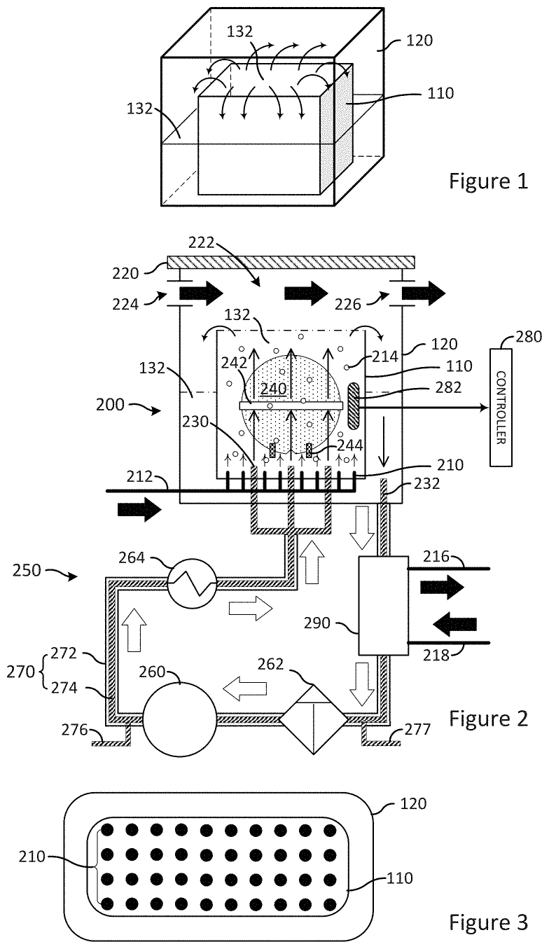

FIG. 1 illustrates a pair of nested tanks of an etching bath used in the embodiments of wet chemical etching systems described in further detail below. The inner tank of the pair may be a process tank 110 filled with an etching solution 132. The outer tank surrounding the process tank 110 may be an overflow tank 120. In FIG. 1, an inflow of the etching solution 132 is shown filling the process tank 110 and an outflow spilling over the edges of an open top of the process tank 110 into the overflow tank 120. Wet chemical baths using a pair of nested tanks, such as illustrated in FIG. 1, is sometimes referred to as a double-walled bath. The process tank 110 and the overflow tank 120 may comprise, for example, quartz, glass, or an inert fluorinated polymer such as polytetrafluoroethylene (PTFE).

FIG. 2 illustrates a cross-sectional view of an etching bath 200 and a recirculation path 250 in accordance with an embodiment of the present application.

The etching bath 200 comprises the process tank 110, the overflow tank 120, a liquid inlet port 230 coupled to a bottom region of the process tank, creating an inflow of etching solution 132 overflowing into the overflow tank 120, and a liquid outlet port 232 coupled to a bottom region of the overflow tank, through which the etching solution 132 may exit the etching bath 200, as depicted by arrows in the etching bath 200 in FIG. 2. In FIG. 2, a substrate 240 (e.g., a semiconductor wafer) is seen immersed in the process tank 110. The substrate 240 may be in a wafer boat 242, which has been placed on a wafer boat holder 244 of the etching bath 200, as shown schematically in FIG. 2. In addition to the substrate 240, the wafer boat 242 may contain a batch of semiconductor wafers comprising a plurality of substrates undergoing the same wet chemical etching process.

The etching bath 200 further comprises a top cover 220 covering the top opening of the etching bath 200 with a material substantially impervious to gas. In an embodiment, the top cover 220 is constructed out of PTFE. In various other embodiments, the material for the top cover 220 may comprise metal, or polyether ether ketone (PEEK). The top cover 220 creates a substantially sealed gaseous space 222 above the level of the liquid etching solution 132 inside the etching bath 200. The seal provided by the top cover 220 helps prevent oxygen in the ambient outside the etching bath 200 from reaching the etching liquid 132, even when the seal is not as effective as that of a high vacuum seal. The gaseous space 222 may be purged with a chemically inert gas such as nitrogen or a noble gas (e.g., argon, helium, and neon) pumped in through a gas inlet 224 and extracted with positive pressure through a gas outlet 226 above the surface of the etching solution, as indicated by solid block arrows. By positive pressure it is implied that the gas pressure at the gas inlet 224 is high enough to ensure that the gas inside the gaseous space 222 can only exit through some other opening of the gaseous space 222; there is no gas leaking into the gaseous space 222 from outside the etching bath 200, except through the gas inlet 224 and from the etching solution 132 (e.g., bubbles of gas injected into the etching solution 132, as described further below).

The gas inlet 224 may be coupled to a gas feed line of a gas flow system that has been configured to supply the chemically inert gas under pressure for purging the gaseous space 222. The gas outlet 226 through which the purge gas is expelled may be coupled to a gas exhaust line of the gas flow system and discarded as exhaust by an exhaust pump. As known to persons skilled in the art, a gas flow system may comprise various components such as high pressure gas canisters, valves (e.g., throttle valves), pressure sensors, gas flow sensors, vacuum pumps, pipes, and electronically programmable controllers. In the example embodiment illustrated in FIG. 2, the gas inlet 224 and the gas outlet 226 of the etching bath 200 are both disposed in the sidewalls of the overflow tank 120 of the etching bath 200. However, it is understood that, in various embodiments, any one or both the gas inlet 224 and the gas outlet 226 may be disposed in the top cover 220.

Purging the gaseous space 222 above the etching solution 132 with the chemically inert gas reduces the likelihood of oxygen in the ambient coming in contact with the liquid-gas interface and contaminating the etching solution 132 with DO. Furthermore, purging with chemically inert gas generally alters the gas-liquid interface such that the equilibrium concentration of DO in the etching solution 132 is lowered.

Degassing of DO from the etching solution 132 may also be achieved by bubbling chemically inert gas such as nitrogen or a noble gas (e.g., argon, helium, and neon) through the etching solution 132 in the process tank 110 with a gas sparger 210 comprising a plurality of gas injectors situated near the bottom of the process tank 110. The plurality of gas injectors configures the gas sparger 210 to distribute the bubbles 214 throughout the volume of the etching solution 132 in the process tank 110. Bubbles provide a large gas-liquid interface area for a given volume of gas. The bubbles 214, comprising chemically inert gas, induce oxygen to diffuse out of the liquid etching solution 132 into the gas bubbles 214. The oxygen extracted into the bubbles 214 may be purged out through the gas outlet 226.

As illustrated in FIG. 2, the gas sparger 210 may receive gas via a coupling to a gas feed line 212 of the gas flow system that has been configured to supply the chemically inert gas used for the bubbles 214. In order to distribute the bubbles 214 uniformly through as much of the volume of the etching solution 132 in the process tank 110 as possible, the gas sparger 210 is designed as an array of gas injectors distributed uniformly across the bottom of the process tank 110.

The planar view in FIG. 3 shows a top view of the distributed gas sparger 210 in accordance with an embodiment of the present application. The gas sparger 210 is disposed in the process tank 110 of the nested pair of tanks comprising the process tank 110 surrounded by the overflow tank 120. In the embodiment illustrated in FIG. 3, the gas sparger 210 is shown to be a rectangular array of closely spaced injectors. Other embodiments may use other arrangements, for example, a circular pattern. The closely spaced injectors of the gas sparger 210 may be in periodic or aperiodic arrangements.

The design of the sparger 210 focuses on creating a uniform and large gas-liquid interface for efficient degassing, unlike a design for a gas sparger used for creating turbulence in the process tank. A few large localized gas injectors may be good for creating turbulence, whereas a greater number of smaller gas injectors distributed uniformly across the bottom of the process tank 110 may be preferred for the sparger 210. The arrangement of the gas injectors, the width of the openings and the space between adjacent injectors may be designed to generate a large number of bubbles 214 distributed uniformly in the process tank 110 providing collectively a large gas-liquid interface area and also spaced close enough to allow oxygen to diffuse from all parts of the etching solution to the gas-liquid interface. In one embodiment, the pitch of the array may be 2 mm to about 20 mm and, in various embodiments from about 1 mm to about 50 mm to cause a substantially uniform injection of the chemically inert gas into the etching solution 132 in the process tank 110.

The example embodiment of the etching bath 200, illustrated in FIG. 2, is configured with two gas inlet ports for receiving the chemically inert gas: the gas inlet 224 disposed above the topmost level of the etching solution 132 in the etching bath, and the gas sparger 210 comprising a plurality of gas injectors situated near the bottom of the process tank 110. In some other embodiment, the gas sparger 210 may double as the gas inlet for purging the gaseous space 222, thereby eliminating some complexity and cost in using separate gas inlets for purging and bubbling.

In the example embodiment in FIG. 2, a DO sensor 282 is shown immersed in the etching solution 132 in the process tank 110. The DO sensor 282 generates an electrical signal when oxygen is sensed entering the sensor body through an oxygen permeable membrane that isolates the sensor from the liquid etching solution 132. The DO sensor 282 may be an optical or a galvanic DO sensor sensitive enough to read a minimum DO concentration in the range of 1 ppb to 10 ppb and detect a change in DO concentration of about 1 ppb in this ultra-low DO concentration regime.

An optical DO sensor is based on the principle that oxygen attenuates the emission from a special luminescent dye that luminesces (e.g., emits red light) when exposed to, for example, a beam of blue light. The DO concentration in the etching solution 132 may be read from the changes in intensity and phase of the luminescence relative to reference waveforms using a photodetector and an analyzer. A galvanic DO sensor comprises an electrolytic cell wherein a reduction reaction with oxygen at the cathode generates an electric current that depends on the diffusion rate of oxygen into the cell. The magnitude of the electric current is used to read the concentration of DO in the etching solution 132.

The output of the DO sensor 282 may be used for process monitoring for passive process control. The DO sensor 282 may also be included in an active process control system. For example, an output signal of the DO sensor 282 may be coupled to a controller 280 that may be programmed to adjust a set of control parameters of the gas flow system. The controller 280 may be part of a feedback control system programmed to maintain the concentration of DO in the etching solution 132 inside the process tank 110 within a specified low concentration range.

The etching bath 200 may be coupled to the recirculation path 250 comprising piping 270 and a pump 260. The recirculation path 250 connects the liquid outlet poll 232, coupled to a bottom region of the overflow tank 120, to the liquid inlet poll 230, coupled to a bottom region of the process tank 110. The pump 260 is used to pump the etching solution 132 to circulate along a recirculation path 250 in a flow out of the overflow tank 120, pass through various components (described below), flow into the process tank 110, and outflow over the edge of its open top, spilling back into the overflow tank 120, as indicated by arrows in FIG. 2. Starting from the liquid outlet port 232, the various components of the recirculation path 250 (mentioned above) comprises a degasser 290, a particle filter 262, and a heat exchanger 264. Recirculation reduces the cost of chemicals added to the etching solution 132, for example, TMAH (chemical formula (CH₃)₄N(OH)) used for etching silicon, but may need replacement as the chemical processing consumes reactants. Periodically, the etching solution 132 may be drained through a drain port 276 and replaced with a freshly prepared solution through a filling port 277, as illustrated in FIG. 2.

The particle filter 262 traps and removes solid particles. Various filters such as membrane filters comprising PTFE, or highly asymmetrical polyarylsulfone (HAPAS) with a pore structure that decreases in size from upstream to downstream surface, and string wound filters comprising PTFE or polyphenylene sulfide (PPS) yarn may be used.

The temperature of the etching solution 132 affects the etching rate and may be adjusted using the heat exchanger 264. A heat exchanger provides the flexibility of heating or cooling a fluid. The heat exchanger 264 may be a countercurrent shell and tube heat exchanger utilizing a countercurrent liquid flow in one embodiment. In other embodiments, the heat exchanger 264 may be of other types such as plate heat exchangers, plate fin heat exchanger and others. The heat exchanger 264 is designed to not introduce chemical contamination of the etching solution 132 while allowing precise control of temperature. The heat exchanger 264 may be controlled by a system controller (not shown) to maintain a desired temperature of the etching solution 132. The desired temperature may be in the range 20° C. to 85° C. in various embodiments, and about 40° C. in the example embodiment, which uses a TMAH solution. The selection and design of the pump 260, the piping 270, and the degasser 290 take into account that a presence of DO in the etching solution 132 is undesirable, as explained below.

The pump 260 may be a pneumatic pump driven by a chemically inert gas such as nitrogen or a noble gas (e.g., argon, helium, and neon) instead of being driven by air.

The piping 270 may comprise double-walled pipes comprising an inner tube 274 to transport the etching solution 132, and a hollow outer sleeve 272. The hollow outer sleeve 272 may be purged with a chemically inert gas to help prevent oxygen from reaching the etching solution by diffusing through the tubing wall of the inner tube 274. The chemically inert gas, such as nitrogen or a noble gas (e.g., argon, helium, and neon) used for purging the hollow outer sleeve 272 may be provided by coupling the hollow outer sleeve 272 to a gas feed line of the gas flow system that has been configured to supply the chemically inert gas.

The degasser 290 along the recirculation path 250 in FIG. 2 may be one of several designs, each based on the principle of using the gas-liquid interface between a chemically inert gas and the etching solution 132 to induce out diffusion of DO from the liquid to the gas. The chemically inert gas may be nitrogen or a noble gas (e.g., argon, helium, and neon). Each embodiment of the recirculation path 250 may insert its respective degasser having its respective technique to create a large area gas-liquid interface. The chemically inert gas may be provided by a gas feed line 218 of the gas flow system that has been configured to supply the chemically inert gas. The chemically inert gas may exit the degasser 290 through an exhaust line 216 of the gas flow system.

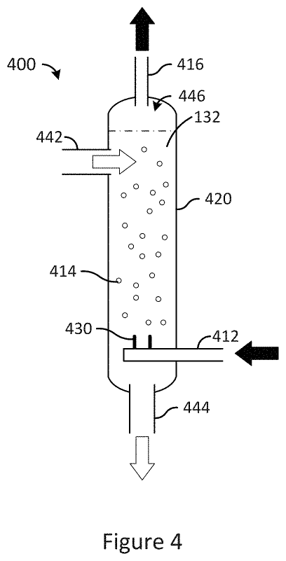

FIG. 4 illustrates a bubble column degasser 400 in accordance with an embodiment of the present application. The bubble column 420, e.g., the housing of the bubble column degasser 400 may comprise quartz, corrosion-resistant metal, or inert polymer such as PTFE or PEEK. As illustrated in FIG. 4, the etching solution 132 is pumped into a bubble column 420 of the bubble column degasser 400 through a liquid inlet port 442 disposed, for example, in a top region of the bubble column 420. Inside the bubble column 420, the etching solution 132 is transported downwards, and exits through a liquid outlet port 444, disposed at the bottom of the bubble column, in this embodiment. When the bubble column degasser 400 is used as the degasser 290 in the recirculation path 250, illustrated in FIG. 2, the liquid inlet port 442 and the liquid outlet port 444 may be coupled to piping 270, and the liquid flow may be driven by the pump 260.

The chemically inert gas may be introduced into the bubble column 420 using a gas sparger 430 positioned, for example, near a bottom region of the bubble column 420. The gas sparger 430 is supplied with chemically inert gas at a gas inlet 412. The bubbles 414 comprising chemically inert gas in the bubble column 420 may be similar to the bubbles 214 introduced into the process tank 110 using the distributed gas sparger 210. The bubbles 414 float to a gaseous region 446 near the top of the bubble column 420, collecting oxygen out diffusing from the etching solution 132 on its way up through the liquid. The gas in gaseous region 446 near the top of the bubble column 420 may be pumped out through a gas outlet 416, disposed at the top of the bubble column 420. The exiting gas may be discarded as exhaust. When the bubble column degasser 400 is used as the degasser 290 in the recirculation path 250, illustrated in FIG. 2, the gas inlet 412 may be coupled to the gas feed line 218 of the gas flow system that has been configured to supply the chemically inert gas. The gas outlet 416 may be coupled to an exhaust line 216 coupled to a vacuum pump of the gas flow system.

It may be noted that the direction of the liquid flow has been designed to be opposite to the direction of the gas flow inside the bubble column 420. The opposing flow directions may help improve the efficiency of DO removal and may provide a lower concentration of DO in the etching solution 132.

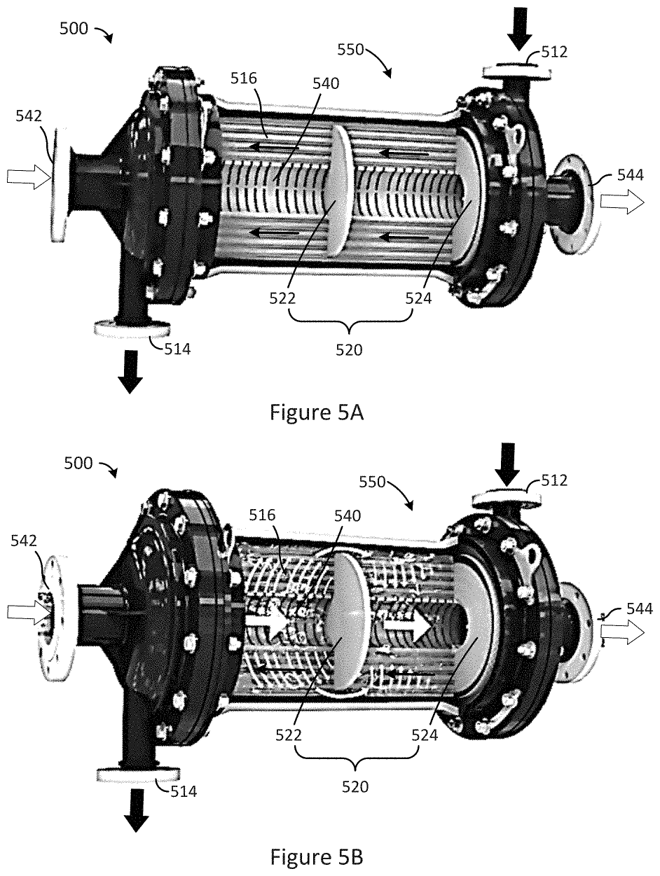

FIGS. 5A and 5B illustrate cutaway views of a membrane filter degasser 500 in accordance with an embodiment of the present application. The membrane filter degasser 500 comprises a liquid inlet port 542 and a liquid outlet port 544. A degassing vessel 550 of the membrane filter degasser 500 is disposed between the liquid inlet port 542 and the liquid outlet port 544. The etching solution 132 may be pumped into a central slotted channel 540 of the degassing vessel 550 through the liquid inlet port 542 and may exit through the liquid outlet port 544. When the membrane filter degasser 500 is used as the degasser 290 in the recirculation path 250, illustrated in FIG. 2, the liquid inlet port 542 and the liquid outlet port 544 may be coupled to piping 270, and the liquid flow may be driven by the pump 260.

Inside the degassing vessel 550, the space around the central slotted channel 540 may be packed with a large number (e.g., several hundreds to several thousands) of hollow fibers 516 arranged with their axes oriented parallel to a central axis of the central slotted channel 540. A chemically inert gas may be introduced into the degassing vessel 550 through a gas inlet 512, enter the hollow fibers 516 in a gaseous compartment near the gas inlet 512 and flow along the fibers 516 in a direction parallel to the direction from the liquid outlet port 544 toward the liquid inlet port 542, as indicated by black arrows inside the degassing vessel 550 in FIG. 5A. The chemically inert gas exits the fibers 516 into a gaseous compartment near the gas outlet 514 and may exit the degasser 500 through the gas outlet 514. When the membrane filter degasser 500 is used as the degasser 290 in the recirculation path 250, illustrated in FIG. 2, the gas inlet 512 may be coupled to the gas feed line 218 of the gas flow system that has been configured to supply the chemically inert gas. The gas outlet 514 may be coupled to an exhaust line 216 coupled to a vacuum pump of the gas flow system.

FIG. 5B shows how the liquid flow inside the degassing vessel may be directed by a system of baffles such as the two-baffle system 520 comprising a first baffle 522 and a second baffle 524, as illustrated in FIG. 5B. After the etching solution 132 enters the central channel, the liquid is forced by the first baffle 522 to flow radially outwards through the slots of the slotted channel over the fibers, as indicated with white arrows. As illustrated in FIG. 5B, the etching solution then flows around the top and bottom of the first baffle 522 to cross over to the opposite side of the degassing vessel 550. There, the second baffle 524 forces the etching solution to return back to the central slotted channel with a radially inward flow, also indicated with white arrows. The liquid etching solution 132 may then flow along the central slotted channel 540 and exit the degassing vessel through the liquid outlet port 544.

The degassing action that removes DO from the etching solution may take place through the fibers 516. The fibers 516 comprise hollow tubes comprising a gas permeable porous membrane. It is to be noted that the material from which the fibers 516 are extruded is hydrophobic. The hydrophobic property of the membrane material prevents the liquid etching solution 132 from entering the fibers 516, but oxygen can pass through because of the gas permeable property of the membrane. An example material that may be used to extrude hollow tubes with the desired properties of the fibers 516 is polypropylene. The fibers effectively provide a gas-liquid interface, the area of which may be large depending on the dimensions of the fibers and that of the pores in the walls that allow oxygen to diffuse into the inner tube of the fiber.

In this disclosure we have described embodiments of wet chemical etching systems and methods that may be used to provide the advantage of 1 to 100 ppb level ultra-low concentration of DO during wet chemical etching. The inventors have performed theoretical analysis and computer aided simulations that suggest that the ultra-low concentrations of DO in an etching solution such as TMAH solution may provide the etching rate uniformity along the depth direction that is desirable to fabricate very high aspect ratio structures such as those used in high density 3D NAND memory cells.

Example 1. A system for semiconductor processing includes an etching bath, which includes a process tank nested inside an overflow tank and has an open top, where the process tank is configured to allow an outflow of an etching solution over the open top into the overflow tank; a wafer boat holder disposed inside the process tank; a top cover configured to substantially seal the etching bath to gas and covering the top opening of the etching bath; a gas inlet disposed outside the process tank; and a gas outlet above a topmost level of the etching solution in the etching bath; and a gas flow system attached to the gas inlet and the gas outlet, where the gas flow system is configured to pump a chemically inert gas into the gas inlet and extract the chemically inert gas through the gas outlet under positive pressure.

Example 2. The system of example 1, further includes a gas sparger which includes a plurality of gas injectors distributed uniformly across a bottom region of the process tank and is coupled to the gas flow system which is configured to bubble a chemically inert gas through the etching solution in the process tank.

Example 3. The system of one of examples 1 or 2, further includes a liquid outlet port coupled to a bottom region of the overflow tank, a liquid inlet port coupled to a bottom region of the process tank, a recirculation path connecting the liquid outlet port to the liquid inlet port, a degasser disposed in the recirculation path, where the degasser is configured to strip dissolved oxygen from the etching solution being recirculated through the recirculation path; and a pump configured to flow the etching solution along the recirculation path into the process tank through the liquid inlet port and out of the overflow tank through the liquid outlet port.

Example 4. The system of one of examples 1 to 3, where the pump is a pneumatic pump driven by a chemically inert gas.

Example 5. The system of one of examples 1 to 4, where the degasser includes a bubble column including a gas sparger, a gas inlet and a gas outlet, the bubble column being coupled to the gas flow system and configured to bubble a chemically inert gas through the etching solution being recirculated through the recirculation path.

Example 6. The system of one of examples 1 to 5, where the degasser includes a membrane filter degasser including a gas inlet, a gas outlet, and high surface area gas permeable fibers, the membrane filter degasser being coupled to the gas flow system and configured to flow a chemically inert gas through the fibers.

Example 7. The system of one of examples 1 to 6, further includes piping configured to circulate the etching solution and disposed in the recirculation path, where the piping includes double-walled pipes that include a gas permeable inner tube to transport the etching solution, and a hollow outer sleeve coupled to the gas flow system configured to flow a chemically inert gas to purge the outer sleeve.

Example 8. The system of one of examples 1 to 7, further includes a dissolved oxygen sensor immersed in the etching solution inside the etching bath, and a control system coupled to the dissolved oxygen sensor and configured to control a dissolved oxygen content in the etching solution by adjusting a control parameter of the gas flow system.

Example 9. A system for semiconductor processing includes an etching bath, which includes a process tank nested inside an overflow tank and has an open top, where the process tank is configured to allow an outflow of an etching solution over the open top into the overflow tank; a wafer boat holder disposed inside the process tank; a top cover configured to substantially seal the etching bath to gas and covering the top opening of the etching bath; and a gas sparger which includes a plurality of gas injectors distributed uniformly across a bottom region of the process tank and coupled to a gas flow system configured to bubble a chemically inert gas through the etching solution in the process tank.

Example 10. The system of example 9, further includes a gas flow system attached to a gas inlet disposed outside the process tank of the etching bath and a gas outlet disposed above a topmost level of the etching solution in the etching bath, the gas flow system configured to pump a chemically inert gas into the gas inlet and extract the chemically inert gas through the gas outlet under positive pressure.

Example 11. The system of one of examples 9 or 10, further includes a gas flow system attached to the gas sparger and a gas outlet disposed above a topmost level of the etching solution in the etching bath, the gas flow system configured to pump a chemically inert gas into the gas sparger and extract the chemically inert gas through the gas outlet under positive pressure.

Example 12. The system of one of examples 9 to 11, further includes a liquid outlet port coupled to a bottom region of the overflow tank, a liquid inlet port coupled to a bottom region of the process tank, a recirculation path connecting the liquid outlet port to the liquid inlet port; a degasser disposed in the recirculation path, where the degasser is configured to strip dissolved oxygen from the etching solution being recirculated through the recirculation path, and a pump configured to flow the etching solution along the recirculation path into the process tank through the liquid inlet port and out of the overflow tank through the liquid outlet port.

Example 13. The system of one of examples 9 to 12, where the degasser includes a bubble column including a gas sparger, a gas inlet and a gas outlet, the bubble column being coupled to the gas flow system and configured to bubble a chemically inert gas through etching solution being recirculated through the recirculation path; or a membrane filter degasser including a gas inlet, a gas outlet, and high surface area gas permeable fibers, the membrane filter degasser being coupled to the gas flow system and configured to flow a chemically inert gas through the fibers and flow the etching solution being recirculated through the recirculation path through the space between the fibers.

Example 14. The system of one of examples 9 to 13, further includes piping configured to circulate the etching solution and disposed in the recirculation path, where the piping includes double-walled pipes including a gas permeable inner tube to transport the etching solution, and a hollow outer sleeve coupled to the gas flow system configured to flow a chemically inert gas to purge the outer sleeve.

Example 15. The system of one of examples 9 to 14, further includes a dissolved oxygen sensor immersed in the etching solution inside the etching bath; and a control system including a controller coupled to the dissolved oxygen sensor and configured to control a dissolved oxygen content in the etching solution by adjusting a control parameter of the gas flow system.

Example 16. A method of semiconductor processing includes filling a process tank of an etching bath disposed inside an overflow tank of the etching bath with an etching solution, immersing a wafer boat with a substrate onto a wafer boat holder inside the process tank, pumping the etching solution from the overflow tank to flow through a degasser, and returning into the process tank, where the pumping of the etching solution causes the etching solution to overflow from the process tank into the overflow tank; and pumping a chemically inert gas through a gas inlet into a region above a topmost level of the etching solution in the overflow tank and extracting the chemically inert gas through a gas outlet under positive pressure.

Example 17. The method of example 16, further includes bubbling a chemically inert gas through the etching solution in the process tank with a gas sparger which includes a plurality of gas injectors distributed uniformly in a bottom region of the process tank and coupled to the gas flow system.

Example 18. The method of one of examples 16 or 17, where pumping the etching solution to flow through a degasser includes flowing the etching solution through a bubble column, and bubbling a chemically inert gas through the etching solution inside the bubble column using a gas sparger and a gas outlet.

Example 19. The method of one of examples 16 to 18, where pumping the etching solution to flow through a degasser includes flowing the etching solution through a membrane filter degasser including high surface area gas permeable fibers, and flowing a chemically inert gas through the fibers.

Example 20. The method of one of examples 16 to 19, where pumping the etching solution along a recirculation path includes flowing the etching solution through double-walled pipes including a gas permeable inner tube and a hollow outer sleeve, and purging the outer sleeve by flowing a chemically inert gas.

Example 21. The method of one of examples 16 to 20, further includes obtaining measurements from a dissolved oxygen sensor placed in the etching solution inside the process tank, and maintaining a concentration of dissolved oxygen in the etching solution inside the process tank by adjusting a control parameter of the gas flow system.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A system for semiconductor processing comprising:
an etching bath comprising:
a process tank nested inside an overflow tank and comprising an open top, wherein the process tank is configured to allow an outflow of an etching solution over the open top into the overflow tank;
a wafer boat holder disposed inside the process tank;
a top cover configured to substantially seal the etching bath to gas and covering the top opening of the etching bath;
a gas inlet disposed outside the process tank; and
a gas outlet above a topmost level of the etching solution in the etching bath; and
a gas flow system attached to the gas inlet and the gas outlet, wherein the gas flow system is configured to pump a chemically inert gas into the gas inlet and extract the chemically inert gas through the gas outlet under positive pressure.

2. The system of claim 1, further comprising a gas sparger comprising a plurality of gas injectors distributed uniformly across a bottom region of the process tank and coupled to the gas flow system configured to bubble a chemically inert gas through the etching solution in the process tank.

3. The system of claim 1, further comprising:
a liquid outlet port coupled to a bottom region of the overflow tank;
a liquid inlet port coupled to a bottom region of the process tank;
a recirculation path connecting the liquid outlet port to the liquid inlet port;
a degasser disposed in the recirculation path, wherein the degasser is configured to strip dissolved oxygen from the etching solution being recirculated through the recirculation path; and
a pump configured to flow the etching solution along the recirculation path into the process tank through the liquid inlet port and out of the overflow tank through the liquid outlet port.

4. The system of claim 3, wherein the pump is a pneumatic pump driven by a chemically inert gas.

5. The system of claim 3, wherein the degasser comprises a bubble column comprising a gas sparger, a gas inlet and a gas outlet, the bubble column being coupled to the gas flow system and configured to bubble a chemically inert gas through the etching solution being recirculated through the recirculation path.

6. The system of claim 3, wherein the degasser comprises a membrane filter degasser comprising a gas inlet, a gas outlet, and high surface area gas permeable fibers, the membrane filter degasser being coupled to the gas flow system and configured to flow a chemically inert gas through the fibers.

7. The system of claim 3, further comprising piping configured to circulate the etching solution and disposed in the recirculation path, wherein the piping comprises double-walled pipes comprising a gas permeable inner tube to transport the etching solution, and a hollow outer sleeve coupled to the gas flow system configured to flow a chemically inert gas to purge the outer sleeve.

8. The system of claim 1, further comprising:
a dissolved oxygen sensor immersed in the etching solution inside the etching bath; and
a control system coupled to the dissolved oxygen sensor and configured to control a dissolved oxygen content in the etching solution by adjusting a control parameter of the gas flow system.

9. A system for semiconductor processing comprising:
an etching bath comprising:
a process tank nested inside an overflow tank and comprising an open top, wherein the process tank is configured to allow an outflow of an etching solution over the open top into the overflow tank;
a wafer boat holder disposed inside the process tank;
a top cover configured to substantially seal the etching bath to gas and covering the top opening of the etching bath; and
a gas sparger comprising a plurality of gas injectors distributed uniformly across a bottom region of the process tank and coupled to a gas flow system configured to bubble a chemically inert gas through the etching solution in the process tank.

10. The system of claim 9, further comprising:
a gas flow system attached to a gas inlet disposed outside the process tank of the etching bath and a gas outlet disposed above a topmost level of the etching solution in the etching bath, the gas flow system configured to pump a chemically inert gas into the gas inlet and extract the chemically inert gas through the gas outlet under positive pressure.

11. The system of claim 9, further comprising:
a gas flow system attached to the gas sparger and a gas outlet disposed above a topmost level of the etching solution in the etching bath, the gas flow system configured to pump a chemically inert gas into the gas sparger and extract the chemically inert gas through the gas outlet under positive pressure.

12. The system of claim 9, further comprising:
a liquid outlet port coupled to a bottom region of the overflow tank;
a liquid inlet port coupled to a bottom region of the process tank;
a recirculation path connecting the liquid outlet port to the liquid inlet port;
a degasser disposed in the recirculation path, wherein the degasser is configured to strip dissolved oxygen from the etching solution being recirculated through the recirculation path; and
a pump configured to flow the etching solution along the recirculation path into the process tank through the liquid inlet port and out of the overflow tank through the liquid outlet port.

13. The system of claim 12, wherein the degasser comprises
a bubble column comprising a gas sparger, a gas inlet and a gas outlet, the bubble column being coupled to the gas flow system and configured to bubble a chemically inert gas through etching solution being recirculated through the recirculation path; or
a membrane filter degasser comprising a gas inlet, a gas outlet, and high surface area gas permeable fibers, the membrane filter degasser being coupled to the gas flow system and configured to flow a chemically inert gas through the fibers and flow the etching solution being recirculated through the recirculation path through the space between the fibers.

14. The system of claim 12, further comprising piping configured to circulate the etching solution and disposed in the recirculation path, wherein the piping comprises double-walled pipes comprising a gas permeable inner tube to transport the etching solution, and a hollow outer sleeve coupled to the gas flow system configured to flow a chemically inert gas to purge the outer sleeve.

15. The system of claim 9, further comprising:
a dissolved oxygen sensor immersed in the etching solution inside the etching bath; and
a control system comprising a controller coupled to the dissolved oxygen sensor and configured to control a dissolved oxygen content in the etching solution by adjusting a control parameter of the gas flow system.

16. A method of semiconductor processing comprising:
filling a process tank of an etching bath disposed inside an overflow tank of the etching bath with an etching solution;
immersing a wafer boat with a substrate onto a wafer boat holder inside the process tank;
pumping the etching solution from the overflow tank to flow through a degasser, and returning into the process tank, wherein the pumping of the etching solution causes the etching solution to overflow from the process tank into the overflow tank; and
pumping a chemically inert gas through a gas inlet into a region above a topmost level of the etching solution in the overflow tank and extracting the chemically inert gas through a gas outlet under positive pressure.

17. The method of claim 16, further comprising:
bubbling a chemically inert gas through the etching solution in the process tank with a gas sparger comprising a plurality of gas injectors distributed uniformly in a bottom region of the process tank and coupled to the gas flow system.

18. The method of claim 16, wherein pumping the etching solution to flow through a degasser comprises:
flowing the etching solution through a bubble column; and
bubbling a chemically inert gas through the etching solution inside the bubble column using a gas sparger and a gas outlet.

19. The method of claim 16, wherein pumping the etching solution to flow through a degasser comprises:
flowing the etching solution through a membrane filter degasser comprising high surface area gas permeable fibers; and
flowing a chemically inert gas through the fibers.

20. The method of claim 16, wherein pumping the etching solution along a recirculation path comprises:
flowing the etching solution through double-walled pipes comprising a gas permeable inner tube, and a hollow outer sleeve; and
purging the outer sleeve by flowing a chemically inert gas.
